(19) United States
(12) Patent Application Publication
(10) Pub. No.: US 2016/0203872 A1
(43) Pub. Date: Jul. 14, 2016

(54) SEMICONDUCTOR MEMORY DEVICE

(71) Applicant: SK hynix Inc., Gyeonggi-do (KR)

(72) Inventor: Byoung Young KIM, Gyeonggi-do (KR)

(21) Appl. No.: 14/727,386

(22) Filed: Jun. 1, 2015

(30) Foreign Application Priority Data
Jan. 12, 2015 (KR) 10-2015-0004211

(51) Int. Cl. G11C 16/26

(52) U.S. Cl. CPC G11C 16/26

(57) ABSTRACT

A semiconductor device includes a memory block including memory cells and an operation circuit configured to perform a read operation which reads LSB data or MSB data stored in the memory cells using different levels of read voltages, wherein when the MSB data is stored in the memory cells, the operation circuit is configured to read the MSB data and the LSB data from the memory cells.

### CROSS-REFERENCE TO RELATED APPLICATION

This application claims priority to Korean Patent Application No. 10-2015-0004211, filed on Jan. 12, 2015, the entire disclosure of which is incorporated herein in its entirety by reference.

### BACKGROUND

1. Field of the Invention

The present invention relates to a semiconductor device and, more particularly, to a semiconductor device including memory cells.

2. Discussion of Related Art

To store a large amount of data in a limited area, a flash memory device may store data having two or more bits in a single memory cell. However, it takes a long time for flash memory devices to determine the data storage status of the memory cells and read the LSB and MSB data. Therefore, a solution to this problem is required.

### SUMMARY

The present invention is directed to a semiconductor device capable of improved operating speed.

One aspect of the present invention provides a semiconductor device comprising a memory block including memory cells and an operation circuit suitable for performing a read operation to read LSB data or MSB data stored in the memory cells using different levels of read voltages, wherein the operation circuit reads the MSB data and the LSB data from the memory cells when the MSB data is stored in the memory cells.

Another aspect of the present invention provides a semiconductor device comprising a memory block including memory cells and an operation circuit suitable for reading LSB data or MSB data stored in the memory cells sequentially using a first read voltage, a second read voltage, and a third read voltage, wherein the second read voltage is higher than the first read voltage, and the third read voltage is higher than the first read voltage and lower than the second read voltage.

Still another aspect of the present invention provides a semiconductor device comprising a memory controller suitable for outputting an LSB read command signal, an MSB read command signal, and a one-shot read command signal and a memory device suitable for outputting LSB data in response to the LSB read command signal, outputting MSB data in response to the MSB read command signal, and outputting the MSB data and the LSB data in response to the one-shot read command signal.

Further aspects of the present invention provides a semiconductor device comprising a memory block including memory cells suitable for storing one or more bits of data, an operation circuit suitable for reading first data from the memory cells using a first read voltage and determining whether the memory cells store MSB data based on the first data, wherein when the memory cells are determined to store the MSB data, the operation circuit reads the MSB data using a second read voltage higher than the first read voltage and reads LSB data using a third read voltage higher than the first read voltage and lower than the second read voltage.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A and 1B are block diagrams illustrating a semiconductor device according to an exemplary embodiment of the present invention;

FIG. 2 is a circuit diagram illustrating a memory block according to an exemplary embodiment of the present invention;

FIGS. 3A to 3C are views illustrating a memory block according to another exemplary embodiment of the present invention;

FIG. 4 is a flow chart illustrating a method of operating the semiconductor device according to the exemplary embodiment of the present invention;

FIGS. 5A and 5B are views illustrating an operating method of the semiconductor device according to the exemplary embodiment of the present invention;

FIG. 6 is a block diagram of a memory system according to an exemplary embodiment of the present invention;

FIG. 7 is a block diagram of a fusion memory device or a fusion memory system which performs a program operation according to various exemplary embodiments of the present invention described above; and

FIG. 8 is a block diagram of a computing system including a flash memory device according to an exemplary embodiment of the present invention.

### DETAILED DESCRIPTION

Advantages and features of the present invention and methods of achieving the same will be described more fully hereinafter with reference to the accompanying drawings, in which exemplary embodiments of the invention are shown. This invention may, however, be embodied in different forms and should not be construed as limited to the embodiments set forth herein. The embodiments of the present invention are provided so that this disclosure is thorough and complete and fully conveys the inventive concept to those skilled in the art, and the spirit and scope of the present invention should be understood by the claims of the present invention.

Throughout the disclosure, like reference numerals correspond directly to the like numbered parts in the various figures and embodiments. In this specification, a singular form may include a plural form as long as it is not specifically mentioned in a sentence. Furthermore, ‘include/comprise’ or ‘including/comprising’ used in the specification represents that one or more components, steps, operations, and elements exist or are added.

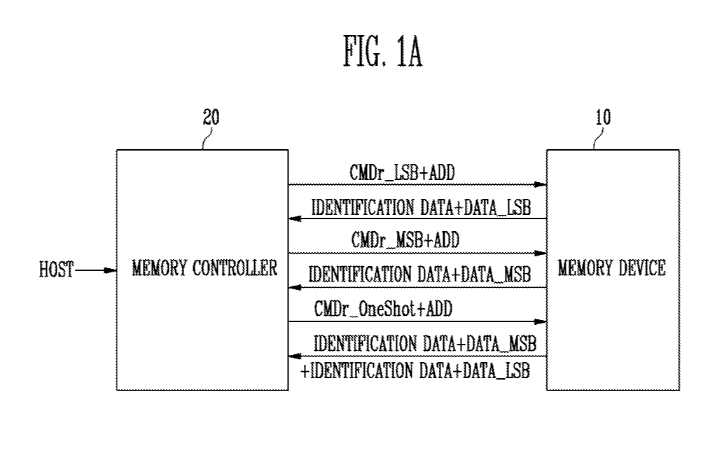

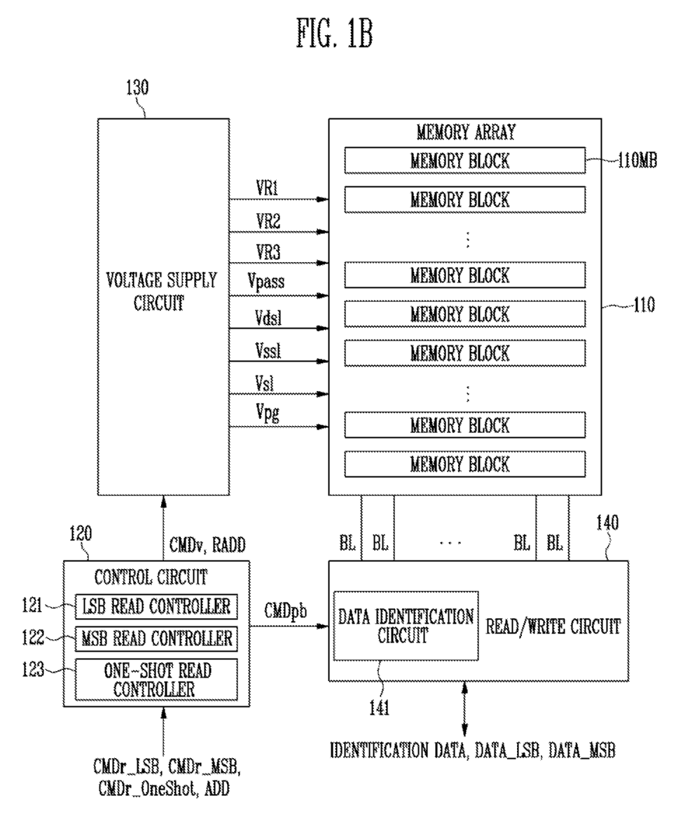

FIGS. 1A and 1B are block diagrams illustrating a semiconductor device according to an exemplary embodiment of the present invention.

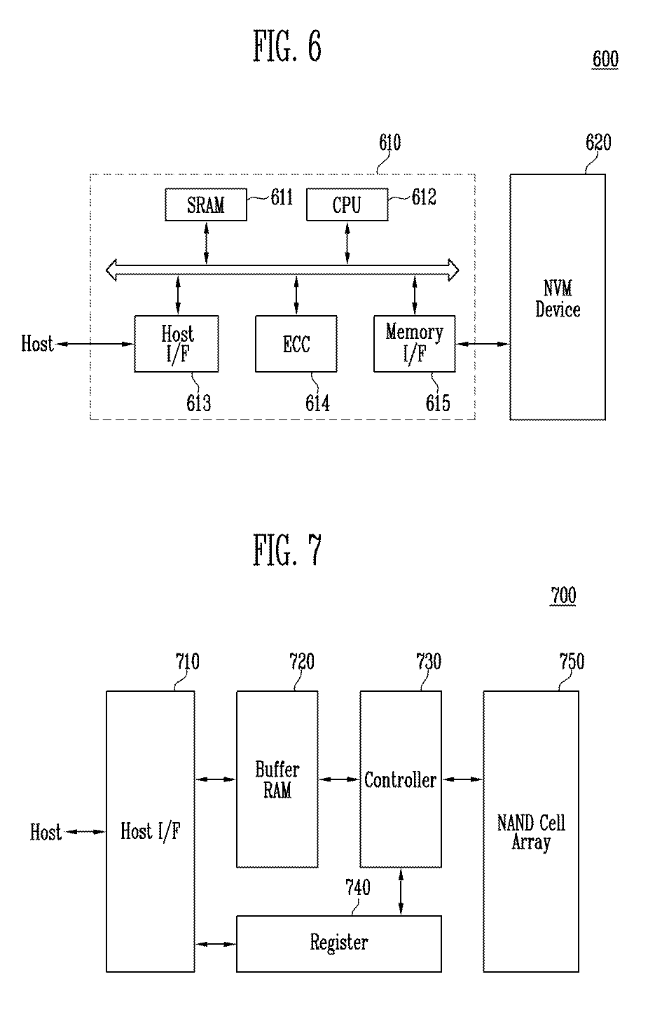

Referring to FIG. 1A, the semiconductor device includes a memory controller 20 and a memory device 10. The memory controller 20 is configured to output one of an LSB read command signal CMDr_LSB, an MSB read command signal CMDr_MSB, and a one-shot read command signal CMDr_OneShot, with an address signal ADD, to the memory device 10 in response to a request from a host HOST. This memory controller 20 may be a memory controller 610 as illustrated in FIG. 6.

The memory device 10 may be configured to read MSB data DATA_MSB by a read operation using first and third read voltages, and read LSB data DATA_LSB by a read operation using a second read voltage higher than the first read voltage but lower than the third read voltage. The memory device 10 may be configured to output the MSB data DATA_MSB followed by the LSB data DATA_LSB in response to the one-shot read command signal CMDr_OneShot.

When the memory device 10 outputs the MSB data DATA_MSB and the LSB data DATA_LSB, the memory device 10 may be configured to output identification data together with the MSB data DATA_MSB and the LSB data DATA_LSB. For example, the memory device 10 may be configured to output the identification data to identify the MSB data DATA_MSB and/or the LSB data DATA_LSB, which are read in response to the LSB read command signal CMDr_LSB, the MSB read command signal CMDr_MSB, or the one-shot read command signal CMDr_OneShot.

This memory device 10 will be described in more detail.

Referring to FIG. 1B, the semiconductor device includes a memory array 110 and operation circuits 120 to 140. The memory array 110 includes a plurality of memory blocks 110MB. Each memory block 110MB includes a plurality of memory strings. Each of the memory strings includes a plurality of memory cells. In the case of a flash memory device, the memory block 110MB may include flash memory cells. The memory cells may include a floating gate formed of polysilicon or a charge storage film (or charge trapping layer) formed of a nitride film.

Particularly, the memory block 110MB may include the memory strings respectively connected to bit lines and connected to a common source line in parallel. The memory strings may be formed to have a two-dimensional structure or three-dimensional structure on a semiconductor substrate. The structure of the memory block 110MB will be described in more detail.

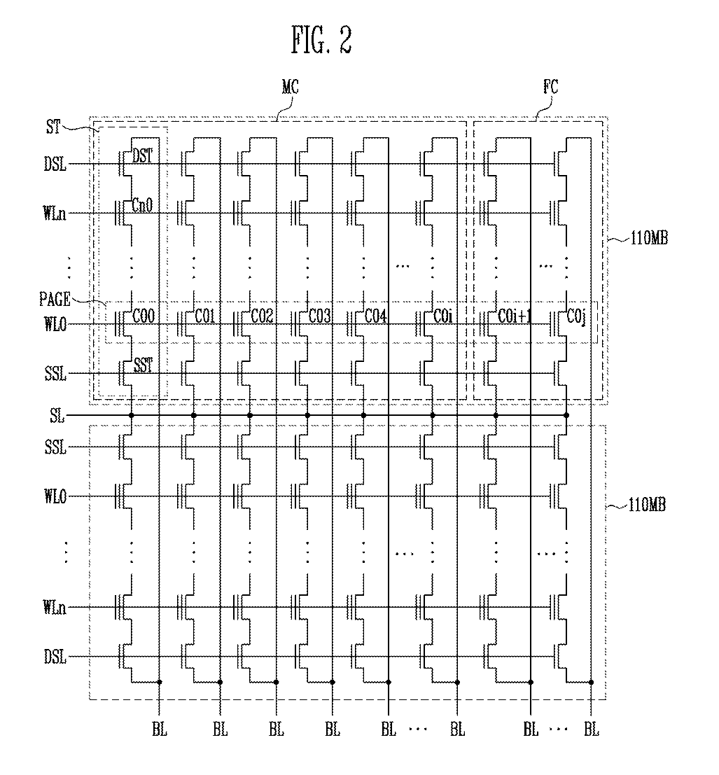

FIG. 2 is a view illustrating a memory array according to an exemplary embodiment of the present invention.

Referring to FIG. 2, each memory block 110MB includes a plurality of memory strings ST connected between bit lines BL and a common source line SL. That is, the memory strings ST are connected to the corresponding bit lines BL, respectively, and are commonly connected to the common source line SL. Each memory string ST includes a source select transistor SST having a source connected to the common source line SL, a drain select transistor DST having a drain connected to a bit line BL, and a cell string. For example, the cell string may include memory cells C00 to Cn0 connected in series between the select transistors SST and DST. A gate of the source select transistor SST is connected to a source select line SSL, and gates of the memory cells C00 to Cn0 are respectively connected to word lines WL0 to WLn, and a gate of the drain select transistor DST is connect to a drain select line DSL.

The drain select transistor DST controls connection or disconnection between the cell string and the bit line BL, and the source select transistor SST controls connection or disconnection between the cell string and the common source line SL.

In the case of the NAND flash memory device, the memory cells included in the memory block 110MB may be classified as a physical page unit or a logical page unit. For example, the memory cells C00 to C0j connected to one word line (e.g., WL0) configure one physical page PAGE. In addition, even-numbered memory cells C00, C02, and C04 to C0j-1 connected to one word line (e.g., WL0) may configure an even-numbered page, and odd-numbered memory cells C01, C03, and C05 to C0j connected to one word line (e.g., WL0) may configure an odd-numbered page. These pages (i.e., the even-numbered page and the odd-numbered page) may be the basic unit of a program operation or a read operation.

Meanwhile, the memory block 110MB may include a main memory cell area MC and a flag memory cell area FC. The main memory cell area MC may include main memory cells C00 to C0i in which first data inputted from the outside (e.g an external device or host) is stored. The flag memory cell area FC may include flag memory cells C0i+1 to C0j in which second data for identifying a type of data stored in the main memory cells C00 to C0i is stored. The main memory cells and the flag memory cells may have the same structure.

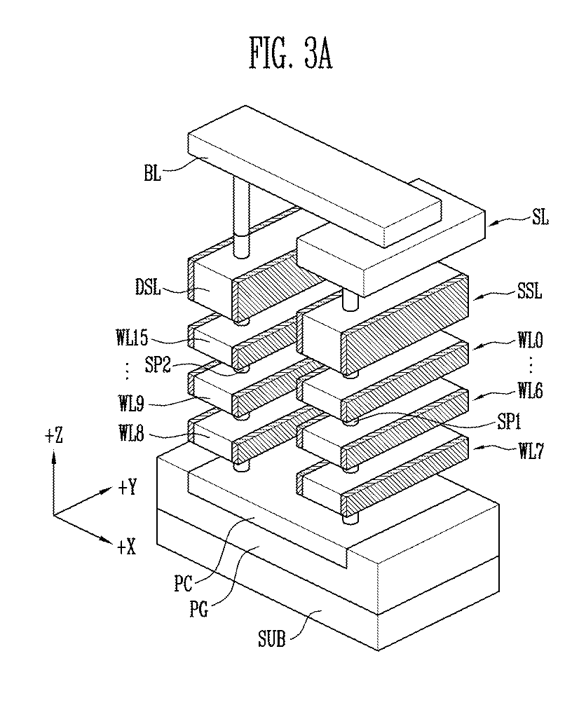

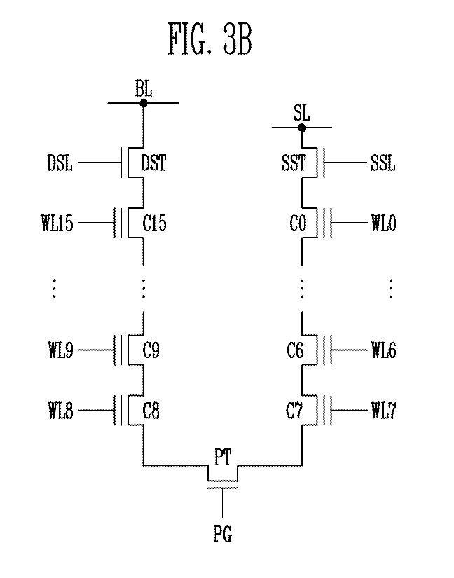

FIGS. 3A to 3C are views illustrating a memory block according to another exemplary embodiment of the present invention.

Referring to FIGS. 3A and 3B, a pipe gate PG including a recessed area is formed on the semiconductor substrate SUB, and a pipe channel layer PC is formed in the recessed area of the pipe gate PG. A plurality of vertical channel layers SP1 and SP2 are formed on the pipe channel layer PC. In a pair of vertical channel layers, the upper part of the first vertical channel layer SP1 is connected to a common source line SL, and the upper part of the second vertical channel layer SP2 is connected to a bit line BL. The vertical channel layers SP1 and SP2 may be formed of polysilicon.

A plurality of first conductive layers DSL and WL15 to WL8 are formed to surround the second vertical channel layer SP2 at different levels thereof. In addition, a plurality of second conductive layers SSL, WL0 to WL7 are formed to surround the first vertical channel layer SP1 at different levels thereof. A multilayer structure (not shown) including a charge trap layer is formed on the surface of the vertical channel layers SP1 and SP2, and on the surface of the pipe channel layer PC, and a multilayer structure is also located between the vertical channel layers SP1 and SP2 and the conductive layers DSL, WL15 to WL8, SSL, and WL0 to WL7, and between the pipe channel layer PC and the pipe gate P.

The uppermost conductive layer surrounding the second vertical channel layer SP2 may serve as the drain select line DSL, and the conductive layers under the drain select line DSL may serve as word lines WL15 to WL8. The uppermost conductive layer surrounding the first vertical channel layer SP1 may serve as the source select line SSL, and the conductive layers under the source select line SSL may serve as word lines WL0 to WL7. Some of the word lines WL0 to WL15 may serve as dummy word lines (not shown).

That is, the first conductive layers SSL and WL0 to WL7 and the second conductive layers DSL and WL15 to WL8 are stacked on different areas of the semiconductor substrate SUB. The first vertical channel layer SP1 passing through the first conductive layers SSL and WL0 to WL7 is vertically connected between the source line SL and the pipe channel layer PC. The second vertical channel layer SP2 passing through the second conductive layers DSL and WL15 to WL8 is vertically connected between the bit line BL and the pipe channel layer PC.

A drain select transistor DST is formed where the drain select line DSL surrounds the second vertical channel layer SP2, and main cell transistors C15 to C8 are respectively formed where the word lines WL15 to WL8 surround the second vertical channel layer SP2. A source select transistor SST is formed where the source select line SSL surrounds the first vertical channel layer SP1, and main cell transistors C0 to C7 are respectively formed where the word lines WL0 to WL7 surround the first vertical channel layer SP1.

Based on the above structure, the memory string may include the drain select transistor DST and the main cell transistors C15 to C8 perpendicularly connected to the semiconductor substrate SUB between the bit line BL and the pipe channel layer PC, and the source select transistor SST and the main cell transistors C0 to C7 vertically connected to the semiconductor substrate SUB between the common source line SL and the pipe channel layer PC. In the above structure, dummy cell transistors (not shown) may also be connected between the select transistor DST or SST and the main cell transistor C15 or C0, and between the main cell transistor C8 or C7 and a pipe transistor PT.

The source select transistor SST and the main cell transistors C0 to C7 connected between the common source line SL and the pipe transistor PT may configure a first vertical memory string, the drain select transistor DST and the main cell transistors C15 to C8 connected between the bit line BL and the pipe transistor PT may configure a second vertical memory string.

Referring to FIG. 3C, a memory block 110MB includes a plurality of memory strings ST connected to bit lines. The U-shaped memory string ST includes a first vertical memory string SST and C0 to C7 vertically connected between a common source line SL and a pipe transistor PT of a substrate SUB, and a second vertical memory string C8 to C15 and DST connected between the bit line BL and the pipe transistor PT of the substrate SUB. The first vertical memory string SST and C0 to C7 includes a source select transistor SST and memory cells C0 to C7 (or the cell transistor of FIG. 3B). The source select transistor SST is controlled by a voltage applied to source select lines Sa1 to SSL4, and the memory cells C0 to C7 are controlled by a voltage applied to stacked word lines WL0 to WL7. The second vertical memory string C8 to C15 and DST includes a drain select transistor DST and memory cells C8 to C15. The drain select transistor DST is controlled by a voltage applied to drain select lines DSL1 to DSL4, and the memory cells C8 to C15 are controlled by a voltage applied to stacked word lines WL8 to WL15.

When the memory block 110MB is selected, a pipe transistor PT connected between a pair of memory cells C7 and C8 located in the middle of the U-shaped memory string performs an operation of electrically connecting the channel layers of the first vertical memory string SST and C0 to C7 to the channel layers of the second vertical memory string C8 to C15 and DST included in the selected memory block 110MB.

Meanwhile, in the case of a memory block of a two dimensional structure, one memory string is connected to each bit line, and drain select transistors of the memory block are simultaneously controlled by one drain select line. In the case of the memory block 110MB of a three dimensional structure, the plurality of memory strings ST are commonly connected to each bit line BL. In the memory block 110MB, the number of the memory strings ST commonly connected to one bit line BL and controlled by the same word lines may depend on circuit design.

Because one bit line BL connects to the plurality of memory strings ST in parallel, the drain select transistors DST are independently controlled by a select voltage applied to the drain select lines DSL1 to DSL4 so as to selectively connect one bit line BL with the memory strings ST.

In the memory block 110MB, the memory cells C0 to C7 of the first vertical memory string SST and C0 to C7 and the memory cells C8 to C15 of the second vertical memory string C8 to C15 and DST, which are vertically connected to each other, are respectively controlled by operating voltages applied to the stacked word lines WL0 to WL7 and the stacked word lines WL8 to WL15. The word lines WL0 to WL15 are classified by each memory block.

The select lines DSL1 to DSL4 and SSL1 to SSL4, and the word lines WL0 to WL15 are local lines of the memory block 110MB. Particularly, the source select lines SSL1 to SSL4 and word lines WL0 to WL7 may be local lines of the first vertical memory string, and the drain select lines DSL1 to DSL4 and word lines WL8 to WL15 may be local lines of the second vertical memory string. In the memory block 110MB, the pipe gates PG of the pipe transistors PT may be commonly connected to a local line.

In the memory block 110MB, memory cells connected to different bit lines and connected to the same word line configure one page PAGE. The memory block 110MB may serve as a basic unit of an erase loop, and a page PAGE may serve as a basic unit of a program operation and a read loop.

As illustrated in the FIG. 2, memory cells connected to some bit lines are used as main memory cells, and memory cells connected to the remaining bit lines are used as flag memory cells.

Referring again to FIGS. 1 and 3B, the operation circuits 120 to 140 are configured to perform an LSB read operation, an MSB read operation, and a one-shot read operation of the memory cells (e.g., C0) connected to the selected word line (e.g., WL0). To perform the read operations, the operation circuits 120 to 140 are configured to sense current flows or voltage changes of the bit lines BL after the bit lines BL are precharged and operating voltages VR1, VR2, VR3, Vpass, Vdsl, Vssl, Vsl, and Vpg are applied to the local lines SSL, WL0 to WLn, PG, and DSL of a selected memory block.

In the case of a NAND flash memory device, an operation circuit includes a control circuit 120, a voltage supply circuit 130, and a read/write circuit 140. Each component will be described below in detail.

The control circuit 120 controls the voltage supply circuit 130 to generate operating voltages VR1, VR2, VR3, Vpass, Vdsl, Vssl, Vsl, and Vpg at desired levels and apply them to the local lines SSL, WL0 to WL15, PG, and DSL and the common source line SL of the selected memory block, in order to perform an LSB read operation, an MSB read operation, or a one-shot read operation in response to read command signals CMDr_LSB, CMDr_MSB, and CMDr_OneShot inputted from the outside. To this end, the control circuit 120 may output a voltage control signal CMDv and a row address signal RADD to the voltage supply circuit 130 in response to the read command signals CMDr_LSB, CMDr_MSB, and CMDr_OneShot and an address signal ADD.

In addition, the control circuit 120 controls the read/write circuit 140 to control precharge/discharge of the bit lines BL or sense a current flow (or a voltage change) of the bit lines BL to perform a program loop, the LSB read operation, the MSB read operation, and the one-shot read operation. To this end, the control circuit 120 may output an operation control signal CMDpb to the read/write circuit 140.

The control circuit 120 may include an LSB read controller 121, an MSB read controller 122, and a one-shot read controller 123. In the LSB read operation, the voltage control signal CMDv and the operation control signal CMDpb may be outputted by the LSB read controller 121. In the MSB read operation, the voltage control signal CMDv and the operation control signal CMDpb may be outputted by the MSB read controller 122. In the one-shot read operation, the voltage control signal CMDv and the operation control signal CMDpb may be outputted by the one-shot read controller 123.

The voltage supply circuit 130 generates the operating voltages VR1, VR2, VR3, Vpass, Vdsl, Vssl, Vsl, and Vpg needed according to the LSB read operation, the MSB read operation, and the one-shot read operation of the memory cells in response to the voltage control signal CMDv of the control circuit 120. The operating voltage may include a first read voltage VR1, a second read voltage VR2, a third read voltage VR3, a pass voltage Vpass, select voltages Vdsl and Vssl, a common source voltage Vsl, a pipe gate voltage Vpg, etc. In addition, the voltage supply circuit 130 outputs the operating voltages to the local lines SSL, WL0 to WLn, PG, and DSL and the common source line SL of a selected memory block in response to the row address signal RADD of the control circuit 120.

The read/write circuit 140 may include a plurality of page buffers (not shown) connected to the memory array 110 through the bit lines BL. Particularly, the page buffers may be connected to the bit lines BL, respectively. That is, one bit line may be connected to one page buffer. In a read operation, the read/write circuit 140 may latch data read from a memory cell by sensing current or voltage changes of the bit lines BL after the bit lines BL are precharged in response to the operation control signal CMDpb of the control circuit 120.

Particularly, the read/write circuit 140 may include a data identification circuit 141. The data identification circuit 141 may be included in a semiconductor device as an independent component separate from the read/write circuit 140.

When the read/write circuit 140 outputs the MSB data DATA_MSB and the LSB data DATA_LSB from the memory cells, the data identification circuit 141 is configured to output identification data together with the MSB data DATA_MSB and the LSB data DATA_LSB. For example, the data identification circuit 141 is configured to output the identification data for identifying the LSB data DATA_LSB as being read from first memory cells storing only the LSB data DATA_LSB or second memory cells storing both the LSB data DATA_LSB and MSB data DATA_MSB. The data identification circuit 141 is also configured to output the identification data for identifying the MSB data DATA_MSB as being read from the second memory cells. Specifically, when the MSB data DATA_MSB is read from the second memory cells, the data identification circuit 141 may output first identification data together with the MSB data DATA_MSB, and when the LSB data DATA_LSB is read from the second memory cells, the data identification circuit 141 may output second identification data together with the LSB data DATA_LSB. In addition, when the LSB data DATA_LSB is read from the first memory cells, the data identification circuit 141 may output third identification data together with the LSB data DATA_LSB.

In another example, when MSB data DATA_MSB is read by the one-shot read operation, the data identification circuit 141 may output first identification data together with the MSB data DATA_MSB, and when LSB data DATA_LSB is read by the one-shot read operation, the data identification circuit 141 may output second identification data together with the LSB data DATA_LSB. In addition, when LSB data DATA_LSB is read by the LSB read operation, the data identification circuit 141 may output third identification data together with the LSB data DATA_LSB, and when MSB data DATA_MSB is read by the MSB read operation, the data identification circuit 141 may output fourth identification data together with the MSB data DATA_MSB.

A semiconductor device including the above configuration identifies data stored in main memory cells using flag data read from flag memory cells. As a result, when only LSB data DATA_LSB is stored in the main memory cells the semiconductor device may output the LSB data DATA_LSB immediately, and when LSB data DATA_LSB and MSB data DATA_MSB are stored in the main memory cells, the semiconductor device may read the LSB data DATA_LSB after the MSB data DATA_MSB is read. In addition, to read the LSB data DATA_LSB and the MSB data DATA_MSB from the main memory cells, the semiconductor device may be configured to sequentially use the first read voltage VR1, the third read voltage VR3 higher than the first read voltage VR1, and the second read voltage VR2 higher than the first read voltage VR1 but lower than the third read voltage VR3.

The first read voltage VR1 may be used when the LSB data DATA_LSB is read from the memory cells in which only the LSB data DATA_LSB is stored. The first and third read voltages VR1 and VR3 may be used when the MSB data DATA_MSB is read from the memory cells in which the LSB data DATA_LSB and the MSB data DATA_MSB are stored, and the second read voltage VR2 may be used when the LSB data DATA_LSB is read from the memory cells in which the LSB data DATA_LSB and the MSB data DATA_MSB are stored.

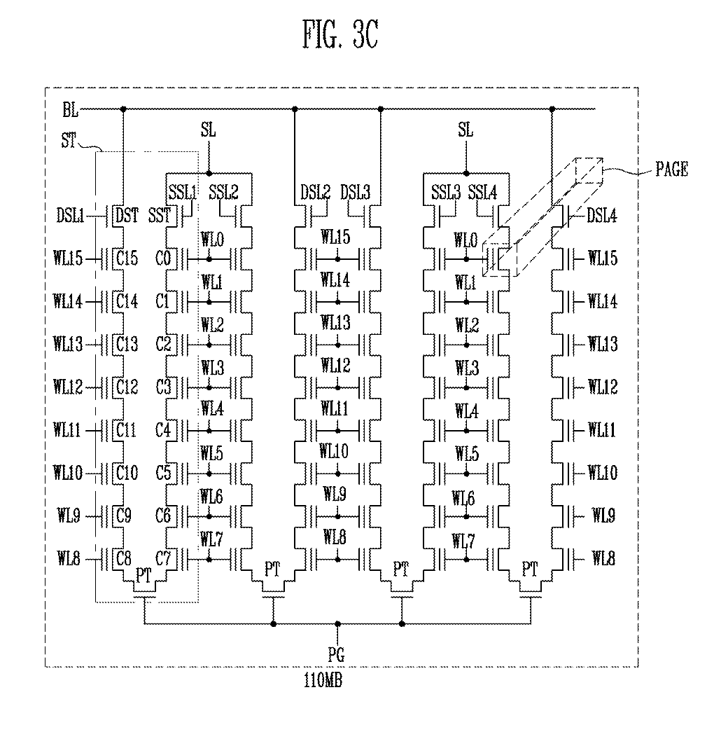

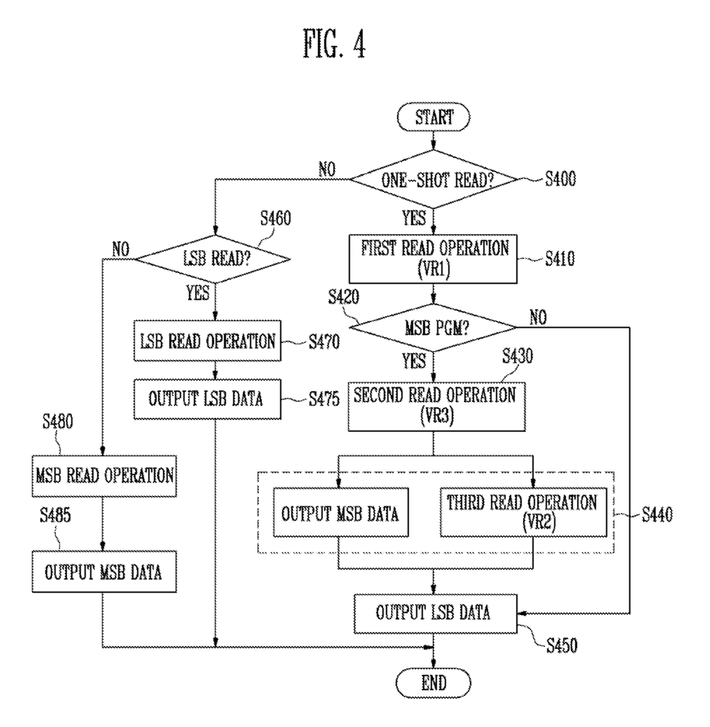

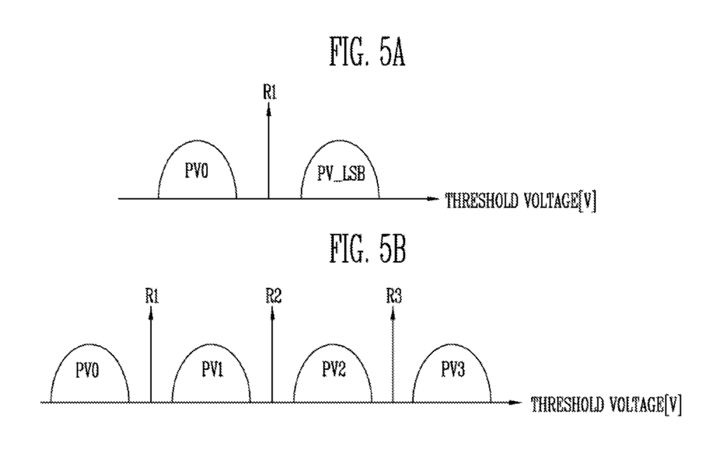

A detailed method of operating the semiconductor device described above will be described below. FIGS. 4, 5A, and 5B are views illustrating an operating method of the semiconductor device according to an exemplary embodiment of the present invention.

Referring to FIGS. 1B, 2, and 4, a read command signal and the address signal ADD are inputted from the memory controller 20 (S400). Whether the read command signal is the one-shot read command signal CMDr_OneShot is determined.

As a result of the determination by the control circuit 120, when the read command signal is the one-shot read command signal CMDr_OneShot, the operation circuits 120 to 140 are controlled to perform the one-shot read operations (S410 to S450) by the one-shot read controller 123 included in the control circuit 120. Details will be described below.

In S410, the operation circuit 120 to 140 performs the first read operation of the memory cells C00 to C0j connected to the selected word line (e.g., WL0). The operation circuits 120 to 140 may selectively use the first to third read voltages VR1, VR2, and VR3 to read the LSB data DATA_LSB or the MSB data DATA_MSB from the main memory cells C00 to C0i. Details will be described below.

Referring to FIG. 5A, when only the LSB data DATA_LSB is stored in the main memory cells C00 to C0i, i.e., when one-bit data is stored in the main memory cell, the threshold voltages of the main memory cells C00 to C0i are separately distributed as an erase level PV0 and an LSB program level PV_LSB. Further, the threshold voltage of a flag memory cell (e.g., C0j) maintains the erase level PV0. The operation circuits 120 to 140 may read the LSB data DATA_LSB from the main memory cells C00 to C0i by the read operation using the first read voltage VR1. That is, the operation circuits 120 to 140 may perform the read operation of the memory cells C00 to C0j using the first read voltage VR1, determine that only the LSB data DATA_LSB is stored in the main memory cells C00 to C0i based on second data (flag data) read from the flag memory cell C0j, and then output first data read from the main memory cells C00 to C0i as the LSB data DATA_LSB.

Referring to FIG. 5B, when the LSB data DATA_LSB and the MSB data DATA_MSB are stored in the main memory cells C00 to C0i, i.e., when two-bit data is stored in the main memory cells, the threshold voltages of the main memory cells C00 to C0i are separately distributed as the erase level PV0 and a plurality of program levels PV1 to PV3. Further, the threshold voltage of a flag memory cell (e.g., C0j) maintains a program level (e.g., PV3). In this case, the operation circuits 120 to 140 may read the MSB data DATA_MSB from the main memory cells C00 to C0i by the read operation using the first and the third read voltages VR1 and VR3. That is, the operation circuits 120 to 140 may perform a first read operation of the memory cells C00 to C0j using the first read voltage VR1, determine that the LSB data DATA_LSB and the MSB data DATA_MSB are stored in the memory cells C00 to C0i based on the flag data read from the flag memory cell C0j, and then output data read from the main memory cells C00 to C0i by additionally performing a second read operation using the third read voltage as the MSB data DATA_MSB. Subsequently, the operation circuits 120 to 140 may perform a third read operation of the memory cells C00 to C0j using the second read voltage VR2, and output data read from the main memory cells C00 to C0i as the LSB data DATA_LSB.

The operation circuits 120 to 140 perform the read operation first using the first read voltage VR1 for determining the LSB data DATA_LSB among the first to third read voltages VR1 to VR3. That is, the operation circuits 120 to 140 perform the first read operation first using the first read voltage VR1 which is the lowest level among the first to third read voltages VR1 to VR3.

Referring again to FIGS. 2 and 4, the operation circuits 120 to 140 perform the first read operation of the memory cells C00 to C0j using the first read voltage VR1. For example, the operation circuits 120 to 140 precharge the bit lines, apply the first read voltage VR1 to the selected word line WL0, apply the pass voltage Vpass to the unselected word lines, and then latch data based on voltage changes of the bit lines.

In S420, the operation circuits 120 to 140 determine whether the first data stored in the main memory cells C00 to C0i includes the LSB data DATA_LSB or includes the LSB data DATA_LSB and the MSB data DATA_MSB based on to the second data read from the flag memory cell C0j by the first read operation. When only the LSB data DATA_LSB is determined to be stored in the main memory cells C00 to C0i, the operation circuits 120 to 140 output the first data read from the main memory cells C00 to C0i by the first read operation as the LSB data DATA_LSB, and the read operation is completed (S450). Here, the data identification circuit 141 of FIG. 1 may output the third identification data for determining that the output data is the LSB data DATA_LSB outputted from the main memory cells C00 to C0i in which only the LSB data DATA_LSB is stored.

When the LSB data DATA_LSB and the MSB data DATA_MSB are determined to be stored in the main memory cells C00 to C0i, the operation circuits 120 to 140 perform the second read operation using the third read voltage VR3 (S430). For example, the operation circuits 120 to 140 precharge the bit lines, supply the third read voltage VR3 to the selected word line WL0, supply the pass voltage Vpass to the unselected word lines, and then latch data based on voltage changes of the bit lines.

As the first and second read operations are performed using the first and the third read voltages VR1 and VR3, the MSB data DATA_MSB read from the main memory cells C00 to C0i is latched in the read/write circuit 140 of the operation circuits 120 to 140.

In S440, the operation circuits 120 to 140 perform the third read operation using the second read voltage VR2 to read the LSB data DATA_LSB from the main memory cells C00 to C0i. For example, the operation circuits 120 to 140 precharge the bit lines, supply the second read voltage VR2 to the selected word line WL0, supply the pass voltage Vpass to the unselected word lines, and then latch data based on voltage changes of the bit lines.

The operation circuits 120 to 140 may output the MSB data DATA_MSB latched in S410 and S430 while the third read operation is performed. That is, the output operation of the MSB data DATA_MSB and the third read operation may be performed simultaneously. Here, the data identification circuit 141 of FIG. 1 may output the first identification data for determining that the output data is the MSB data DATA_MSB read from the main memory cells C00 to C0i in which the LSB data DATA_LSB and the MSB data DATA_MSB are stored.

In S450, the operation circuits 120 to 140 output the LSB data DATA_LSB read from the main memory cells C00 to C0i by the third read operation using the second read voltage VR2. Here, the data identification circuit 141 of FIG. 1 may output the second identification data for determining that the output data is the LSB data DATA_LSB read from the main memory cells C00 to C0i in which the LSB data DATA_LSB and the MSB data DATA_MSB are stored.

Since the read operation is performed as described above, the operating speed of the semiconductor device can be improved.

Meanwhile, in S400, when the read command signal is determined not to be the one-shot read command signal CMDr_OneShot by the control circuit 120, the control circuit 120 determines whether a read command signal is the LSB read command signal CMDr_LSB (S460). As a determination result of the control circuit 120, when the read command signal is the LSB read command signal CMDr_LSB, the operation circuits 120 to 140 are controlled to perform the LSB read operation by the LSB read controller 121 included in the control circuit 120 (S470).

For the LSB read operation, the operation circuits 120 to 140 precharge the bit lines BL, supply a read voltage to the selected word line (e.g., WL0), and supply a pass voltage Vpass to the remaining word lines. Here, when only one-bit data (e.g., LSB data) is stored in the memory cells, the operation circuits 120 to 140 may apply the first read voltage VR1 to the selected word line for the LSB read operation. When two-bit data (e.g., the LSB data and the MSB data) is stored in the memory cells, the operation circuits 120 to 140 may apply the second read voltage VR2 to the selected word line for the LSB read operation. Further, the operation circuits 120 to 140 sense voltage (or current) changes of the bit lines BL, and latch the sensing result.

In S475, the operation circuits 120 to 140 may output the LSB data DATA_LSB together with the third identification data.

When the read command signal is determined as the MSB read command signal CMDr_MSB from the determination result of the control circuit 120 in S460, the operation circuits 120 to 140 are controlled to perform the MSB read operation by the MSB read controller 122 included in the control circuit 120 (5480).

For the MSB read operation, the operation circuits 120 to 140 precharge the bit lines BL, apply a read voltage to a selected word line (e.g., WL0), and apply the pass voltage Vpass to the remaining word lines. Here, the operation circuits 120 to 140 sense voltage (or current) changes of the bit lines BL by a read operation using the first read voltage VR1, and latch the sensing result. Next, the operation circuits 120 to 140 sense voltage (or current) changes of the bit lines BL by a read operation using the third read voltage VR3, and latch the sensing result.

In S475, the operation circuits 120 to 140 may output fourth identification data together with the MSB data DATA_MSB using the latched sensing result.

As described above, the memory device may separately perform the LSB read operation, the MSB read operation, and the one-shot read operation in response to a read command signal inputted from the memory controller.

FIG. 6 is a block diagram of a memory system according to an exemplary embodiment of the present invention.

Referring to FIG. 6, a memory system 600 according to an exemplary embodiment of the present invention includes a nonvolatile memory (NVM) device 620 and a memory controller 610.

The NVM device 620 may correspond to the semiconductor device illustrated in FIGS. 1 to 5. The memory controller 610 may be configured to control the NVM device 620. The memory system 600 including the nonvolatile memory device 620 and the memory controller 610 may be provided as a memory card or a semiconductor disk device (i.e., solid state disk (SSD)). An SRAM 611 is used as an operational memory of a central processing unit (CPU) 612. A host interface 613 includes a data exchange protocol for interfacing with a host Host to be connected to the memory system 600. An error correction code block (ECC) 614 detects and corrects errors included in data read from a cell area of the NVM device 620. A memory interface 615 interfaces with the NVM device 620. The CPU 612 performs overall operations for data exchange of the memory controller 610.

Although not shown in the drawing, it is apparent to those of ordinary skill in the art that the memory system 600 according to the exemplary embodiment of the present invention may also be provided with a ROM (not shown) in which code data for interfacing with a host Host may be stored. The NVM device 620 may be provided as a multi-chip package including a plurality of flash memory chips. The memory system 600 according to the exemplary embodiment of the present invention may be provided as a high reliability storage medium in which the operational characteristics are improved. Particularly, the flash memory device according to the embodiment of the present invention may be included in a memory system such as a semiconductor disk device (SSD). In this case, the memory controller 610 may be configured to communicate with the outside (e.g., a host Host) through one of various interface protocols such as USB, MMC, PCI-E, SATA, PATA, SCSI, ESDI, IDE, etc.

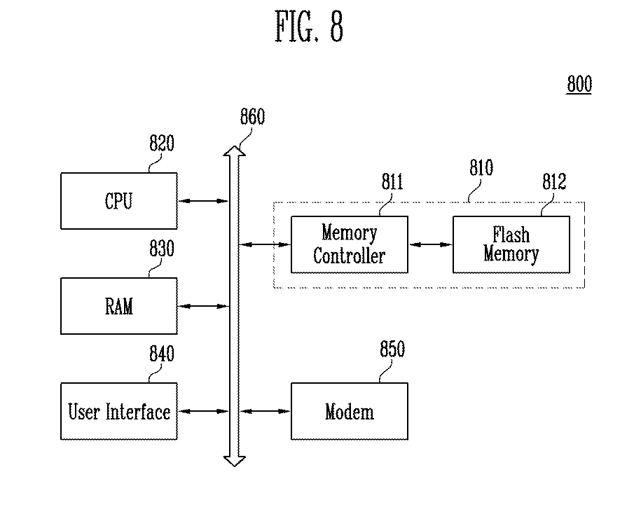

FIG. 7 is a block diagram of a fusion memory device or a fusion memory system which performs a program operation. For example, the aspects of the present invention illustrated in the FIGS. 1 to 5 may be applied to a OneNAND flash memory device 700 as a fusion memory device.

The OneNAND flash memory device 700 includes a host interface 710, a buffer RAM 720, a controller 730, a register 740, and a NAND (flash) cell array 750. The host interface 710 may exchange various types of data with a device using a different protocol. The buffer RAM 720 may have a embedded-code for driving the memory device 700 or temporarily store data. The controller 730 may control a read operation, a program operation, and all states in response to a control signal and a command inputted from the outside. The register 740 may store data, such as a command, an address, and a configuration defining a system operational environment inside the memory device 700. The NAND (flash) cell array 750 is configured with an operation circuit including non-volatile memory cells and page buffers. The OneNAND flash memory device programs data in a general method in response to a write operation request from a host Host.

FIG. 8 is a block diagram of a computing system including a flash memory 812 according to the exemplary embodiment of the present invention.

A computing system 800 according to the exemplary embodiment of the present invention includes a microprocessor (CPU) 820, a RAM 830, a user interface 840, a modem 850 such as a baseband chipset, and a memory system 810 electrically connected to a system bus 860. When the computing system 800 according to the exemplary embodiment of the present invention is a mobile device, a battery (not shown) may be additionally provided to supply an operating voltage of the computing system 800. Although not shown in the drawing, it is apparent to those of ordinary skill in the art that the computing system 800 according to the exemplary embodiment of the present invention may also be provided with an application chipset, a camera image processor (CIS), a mobile DRAM, etc. For example, the memory system 810 may configure an SSD using the non-volatile memory illustrated in FIGS. 1 to 5 to store data. In addition, the memory system 810 may be provided as a fusion memory (e.g., OneNAND flash memory).

The semiconductor device according to the exemplary embodiments of the present invention can improve the operating speed thereof.

In the drawings and specification, there have been disclosed typical exemplary embodiments of the invention, and although specific terms are employed, they are used in a generic and descriptive sense only and not for purpose of limitation. As for the scope of the invention, it is to be set forth in the following claims. Therefore, it will be understood by those of ordinary skill in the art that various changes in form and detail may be made therein without departing from the spirit and scope of the present invention as defined by the following claims.

What is claimed is:

1. A semiconductor memory device comprising:
a memory block including memory cells; and
an operation circuit suitable for performing a read operation to read LSB data or MSB data stored in the memory cells using different levels of read voltages,
wherein when the MSB data is stored in the memory cells, the operation circuit reads the MSB data and the LSB data from the memory cells.

2. The semiconductor memory device of claim 1, wherein the memory cells include:
main memory cells suitable for storing first data inputted from the outside; and
flag memory cells suitable for storing second data for determining a type of the first data.

3. The semiconductor memory device of claim 2, wherein the operation circuit performs the read operation on the memory cells using a selected read voltage, and determines whether the MSB data is stored in the memory cells on which the read operation is performed, using data read from the flag memory cells.

4. The semiconductor memory device of claim 3, wherein the selected read voltage corresponds to a lowest read voltage of the read voltages.

5. The semiconductor memory device of claim 1, wherein the operation circuit performs the read operation sequentially using a lowest read voltage and a highest read voltage among the read voltages to read the MSB data from the memory cells.

6. The semiconductor memory device of claim 1, wherein the operation circuit performs the read operation using an intermediate level read voltage among the read voltages to read the LSB data after the MSB data is read from the memory cells.

7. The semiconductor memory device of claim 1, wherein the operation circuit outputs the MSB data read from the memory cells while reading the LSB data from the memory cells.

8. The semiconductor memory device of claim 1, wherein the operation circuit includes:
a data identification circuit suitable for outputting identification data when the operation circuit outputs the MSB data and the LSB data.

9. The semiconductor memory device of claim 8, wherein the data identification circuit outputs the identification data for identifying the LSB data as being read from memory cells storing only the LSB data or both the LSB data and the MSB data and identifying the MSB data followed by the LSB data.

10. The semiconductor memory device of claim 1, wherein the operation circuit performs the read operation first using a read voltage, among the read voltages, which allows the LSB data to be determined.

11. The semiconductor memory device of claim 1, wherein the operation circuit performs the read operation first using a lowest read voltage among the read voltages.

12. A semiconductor memory device comprising:
a memory block including memory cells; and
an operation circuit suitable for reading LSB data or MSB data stored in the memory cells sequentially using a first read voltage, a second read voltage, and a third read voltage,
wherein the second read voltage is higher than the first read voltage, and the third read voltage is higher than the first read voltage and lower than the second read voltage.

13. The semiconductor memory device of claim 12, wherein the operation circuit reads the MSB data by a read operation using the first and second read voltages, and reads the LSB data by a read operation using the third read voltage.

14. The semiconductor memory device of claim 12, wherein the operation circuit performs a read operation to read the LSB data after reading the MSB data.

15. The semiconductor memory device of claim 12, wherein the operation circuit includes:
a data identification circuit suitable for outputting identification data when the operation circuit outputs the MSB data and the LSB data.

16. The semiconductor memory device of claim 15, wherein the data identification circuit outputs the identification data for identifying the LSB data as being read from memory cells storing only the LSB data or both the LSB data and the MSB data and identifying the MSB data followed by the LSB data.

17. A semiconductor memory device comprising:
a memory controller suitable for outputting an LSB read command signal, an MSB read command signal, and a one-shot read command signal; and
a memory device suitable for outputting LSB data in response to the LSB read command signal, outputting MSB data in response to the MSB read command signal, and outputting the MSB data and the LSB data in response to the one-shot read command signal.

18. The semiconductor memory device of claim 17, wherein the memory device reads the MSB data by a read operation using a first read voltage and a second read voltage, higher than the first read voltage, and reads the LSB data by a read operation using a third read voltage, higher than the first read voltage and lower than the second read voltage.

19. The semiconductor memory device of claim 17, wherein the memory device outputs the MSB data followed by the LSB data in response to the one-shot read command signal.

20. The semiconductor memory device of claim 17, wherein the memory device outputs identification data which determines the LSB data read in response to the LSB read command signal, the MSB data read in response to the MSB read command signal, and the MSB data and the LSB data read in response to the one-shot read command signal.
